(19) United States
(12) Patent Application Publication
(10) Pub. No.: US 2008/0001250 A1
(43) Pub. Date: Jan. 3, 2008

(54) Semiconductor device and fabrication method therefor

(76) Inventors: Hideo Ichimura, Toyama (JP); Takashi Nakabayashi, Toyama (JP)

Correspondence Address: MCDERMOTT WILL & EMERY LLP, 600 13TH STREET, NW, WASHINGTON, DC, 20005-3096, US

(21) Appl. No.: 11/714,900

(22) Filed: Mar. 7, 2007

(30) Foreign Application Priority Data
Jun. 30, 2006 (JP) 2006-181947

(51) Int. Cl. H01L 29/00; H01L 21/44

(52) U.S. Cl. 257/529; 438/601; 257/E21.476; 257/E29.001

(57) ABSTRACT

A semiconductor device has a capacitor including a first lower electrode, a capacitor insulating film, and a first upper electrode which are successively formed above a substrate and a fuse element including a second lower electrode, a fuse insulating film, and a second upper electrode which are successively formed above a different region of the substrate from the region thereof on which the capacitor is formed. The first lower electrode is formed to have a depressed cross-sectional configuration. The second lower electrode has a columnar configuration and is made of the same conductive material as the first lower electrode.

### CROSS REFERENCE TO RELATED APPLICATIONS

The teachings of Japanese Patent Application JP 2006-181947, filed Jun. 30, 2006, are entirely incorporated herein by reference, inclusive of the claims, specification, and drawings.

### BACKGROUND OF THE INVENTION

The present invention relates to a semiconductor device and a fabrication method therefor and, more particularly, to a semiconductor device having a memory circuit and a logic circuit each embedded therein and comprising a fuse element and a fabrication method therefor.

The higher integration of semiconductor devices, especially semiconductor memory devices represented by a dynamic random access memory (DRAM) device, has been increasingly promoted. The DRAM device is formed of a large number of integrated memory cells. Even when any of the integrated memory cells needed for 1-bit storage becomes defective, the entire device becomes defective. To prevent the entire device from becoming defective, a technology has been used which preliminarily provides a redundant circuit and replaces the defective bit by using the redundant circuit. For example, when fuse elements which can be broken with laser light are formed in a semiconductor chip and a defective bit occurs, the one of the fuse elements which corresponds to the defective bit is broken by irradiating it with laser light so that the defective bit is replaced with the redundant circuit.

As the integration of a semiconductor device becomes higher, the number of fuse elements required in one device increases. Therefore, it has been required to reduce the size of each of the fuse elements and arrange the fuse elements at a high density. However, because the spot of laser light for breaking a fuse element has not been reduced in size, the spacings between individual fuse elements cannot be reduced. In view of this, a technology which uses fuse elements (anti-fuses) each having an insulating film that is broken down by the application of a specified voltage in a semiconductor chip, in place of fuse elements breakable with laser light, has drawn attention.

Another technology has also been disclosed which allows simultaneous formation of fuse elements and the memory elements of a DRAM device by forming insulating elements serving as the fuse elements such that they have the same structures as the memory elements and thereby prevents an increase in the number of process steps resulting from the formation of the fuse elements (see, e.g., Japanese Laid-Open Patent Publication No. 2000-123592).

However, since the conventional anti-fuse elements have the same structures as memory cell capacitors serving as the memory elements, there are restrictions on alignment between lower electrodes and upper electrodes, alignment between the upper electrodes and bit-line contacts, and the like. As a result, there has been a problem that the spacings between the individual fuse elements cannot be reduced and the area of a region in which the fuse elements are formed increases, which is disadvantageous for higher integration of a semiconductor device.

### SUMMARY OF THE INVENTION

It is therefore an object of the present invention to solve the conventional problems described above and implement a semiconductor device wherein the area of a region in which fuse elements are formed can be reduced without increasing the number of process steps.

To attain the object, the present invention constructs a semiconductor device comprising a capacitor including a lower electrode having a depressed cross-sectional configuration and a fuse element including a lower electrode having a columnar configuration, which are formed of the same material.

Specifically, a semiconductor device according to the present invention comprises: a capacitor including a first lower electrode, a capacitor insulating film, and a first upper electrode which are successively formed above a substrate; and a fuse element including a second lower electrode, a fuse insulating film, and a second upper electrode which are successively formed above a different region of the substrate from a region thereof on which the capacitor is formed, wherein the first lower electrode is formed to have a depressed cross-sectional configuration and the second lower electrode has a columnar configuration and is made of the same conductive material as the first lower electrode.

The semiconductor device according to the present invention allows a reduction in the size of the fuse element. Therefore, even when the capacitors and the fuse elements are formed by using the same mask and using a uniform pitch pattern, the fuse elements can be formed at a high density. As a result, the area of the region on which the fuse elements are formed is reduced and the integration of the semiconductor device can be thereby improved. Moreover, because the capacitors and the fuse elements can be formed by the same process, there is no increase in the number of the steps of forming the fuse elements.

In the semiconductor device according to the present invention, a width of the second lower electrode is preferably less than double a film thickness of the first lower electrode. The arrangement allows reliable formation of the fuse element having the columnar lower electrode and the capacitor by the same process.

In the semiconductor device according to the present invention, the capacitor insulating film and the fuse insulating film are preferably made of the same insulating material and the first upper electrode and the second upper electrode are preferably made of the same conductive material. The arrangement allows reliable formation of the capacitor and the fuse element by the same process.

Preferably, the semiconductor device according to the present invention further comprises: a first interlayer insulating film formed on the substrate; and a second interlayer insulating film formed on the first interlayer insulating film and having a first opening and a second opening each reaching the first interlayer insulating film, wherein the first lower electrode is formed to cover the bottom and wall surfaces of the first opening, the second lower electrode is formed to fill the second opening, and a width of the first opening is larger than double a total sum of a film thickness of the first lower electrode and a thickness of the capacitor insulating film. The arrangement allows reliable formation of the first lower electrode of the capacitor which has the depressed cross-sectional configuration and the second lower electrode of the fuse element which has the columnar configuration by the same process.

In the semiconductor device according to the present invention, the capacitor insulating film and the first upper electrode are preferably formed to cover the side and upper surfaces of the first lower electrode and the fuse insulating film and the second upper electrode are preferably formed to cover the upper surface of the second lower electrode.

The arrangement allows a concave capacitor and the fuse element to be formed by the same process steps.

In other structures, a first interlayer insulating film formed on the substrate may further be provided, the first lower electrode and the second lower electrode may be formed to upwardly protrude from the upper surface of the first interlayer insulating film, the capacitor insulating film and the first upper electrode may be formed to cover the side and upper surfaces of the first lower electrode, and the fuse insulating film and the second upper electrode may be formed to cover the side and upper surfaces of the second lower electrode. The arrangement allows a cylindrical capacitor and the fuse element to be formed by the same process steps.

In the semiconductor device according to the present invention, each of the capacitor insulating film and the fuse insulating film is preferably made of a metal oxide. In this case, the metal oxide is preferably an oxide of hafnium. The arrangement can implement low-voltage programmable fuse elements.

A method for fabricating a semiconductor device according to the present invention comprises the steps of: (a) forming a first interlayer insulating film on a substrate; (b) forming a second interlayer insulating film on the first interlayer insulating film and then forming a first opening and a second opening having a width smaller than a width of the first opening such that each of the first opening and the second opening extends through the formed second interlayer insulating film; (c) after the step (b), forming a lower-electrode forming film above the substrate; (d) removing a portion of the lower-electrode forming film which is formed on the upper surface of the second interlayer insulating film to form a first lower electrode having a depressed cross-sectional configuration in the first opening and form a second lower electrode having a columnar configuration in the second opening; and (e) after the step (d), forming a capacitor insulating film covering the first lower electrode and a first upper electrode and simultaneously forming a fuse insulating film covering the second lower electrode and a second upper electrode.

The method for fabricating a semiconductor device according to the present invention allows the lower electrode of the capacitor which has the depressed configuration and the lower electrode of the fuse element which has the columnar configuration to be formed by the same process. In addition, because the capacitor insulating film, the upper electrode of the capacitor, the fuse insulating film, and the upper electrode of the fuse element can be formed by the same process, a semiconductor device comprising fuse elements can be implemented without increasing the number of process steps. Moreover, because the fuse element can be formed to have dimensions smaller than those of the capacitor, the fuse elements can be formed at a high density even when the capacitors and the fuse elements are formed at the same pitch by using the same mask. As a result, it is possible to implement a semiconductor device wherein the region on which the fuse elements are formed occupies a small area.

In the method for fabricating a semiconductor device according to the present invention, the second openings is preferably formed in the step (b) to have a width which is less than double a thickness of the lower-electrode forming film. The arrangement allows reliable formation of the second lower electrode having a columnar configuration in the second opening.

In the method for fabricating a semiconductor device according to the present invention, the first opening is preferably formed in the step (b) to have a width which is larger than double a total sum of a thickness of the lower-electrode forming film and a thickness of the capacitor insulating film. The arrangement allows reliable formation of the first lower electrode having the depressed cross-sectional configuration in the first opening even when the second lower electrode is formed to fill the second opening.

In the method for fabricating a semiconductor device according to the present invention, the step (e) preferably includes successively forming an insulating film and an upper-electrode forming film above the substrate and then patterning the insulating film and the upper-electrode forming film to form the capacitor insulating film and the first upper electrode as well as the fuse insulating film and the second upper electrode.

Preferably, the method for fabricating a semiconductor device according to the present invention further comprises the step of: after the step (d) and before the step (e), removing the second interlayer insulating film. The arrangement allows a cylindrical capacitor and the fuse element to be formed by the same process steps.

### BRIEF DESCRIPTION OF THE DRAWINGS

FIG. 1 is a cross-sectional view of a semiconductor device according to a first embodiment of the present invention;

FIGS. 2A to 2C are cross-sectional views illustrating a method for fabricating the semiconductor device according to the first embodiment in the order in which the process steps thereof are performed;

FIGS. 3A to 3C are cross-sectional views illustrating the method for fabricating the semiconductor device according to the first embodiment in the order in which the process steps thereof are performed;

FIGS. 4A and 4B are cross-sectional views illustrating the method for fabricating the semiconductor device according to the first embodiment in the order in which the process steps thereof are performed;

FIG. 5 is a cross-sectional view of a semiconductor device according to a second embodiment of the present invention;

FIGS. 6A and 6B are cross-sectional views illustrating a method for fabricating the semiconductor device according to the second embodiment in the order in which the process steps thereof are performed; and

FIGS. 7A and 7B are cross-sectional views illustrating the method for fabricating the semiconductor device according to the second embodiment in the order in which the process steps thereof are performed.

### DETAILED DESCRIPTION OF THE INVENTION

### Embodiment 1

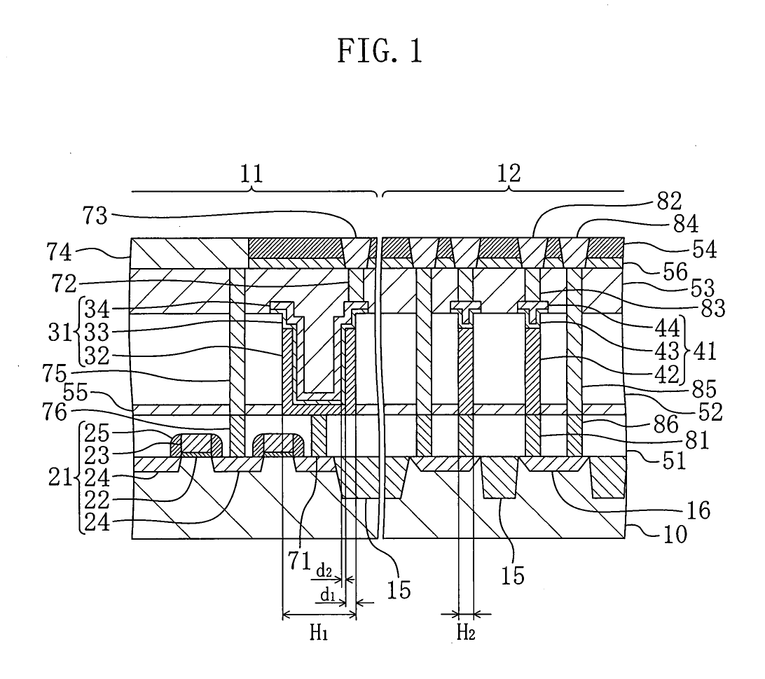

A first embodiment of the present invention will be described with reference to the drawings. FIG. 1 shows a cross-sectional structure of a semiconductor device according to the first embodiment.

As shown in FIG. 1, the semiconductor device according to the present embodiment is a dynamic random access memory (DRAM) device having memory cells each with a 1-transistor 1-capacitor configuration. The memory cells each including a MIS transistor (hereinafter referred to as “transistor”) 21 and a capacitor 31 are formed in the memory cell region 11 of a semiconductor substrate (hereinafter referred to as “substrate”) 10 made of silicon or the like. A plurality of fuse elements 41 are formed in the fuse region 12 of the substrate 10.

The transistors 21 are formed individually in element formation regions each defined by an isolation film 15 in the substrate 10. The transistor 21 has a gate electrode 23 formed on the substrate 10 with a gate insulating film 22 interposed therebetween, source/drain diffusion layers 24 formed individually on the portions of each of the element formation regions which are located on both sides of the gate electrode 23, and insulating sidewalls 25 formed on the side surfaces of the gate electrode 23.

Each of the capacitors 31 is formed on a first interlayer insulating film 51 formed on the substrate 10 to cover the transistors 21 and electrically connected to one of the source/drain regions 24 by a plug 71 extending through the first interlayer insulating film 51. The capacitor 31 has a concave three-dimensional structure in which a first lower electrode 32 serving as the lower electrode of the capacitor and having a depressed cross-sectional configuration, a capacitor insulating film 33, and a first upper electrode 34 serving as the upper electrode of the capacitor are successively formed.

The first lower electrode 32 is formed to have the depressed cross-sectional configuration in such a manner as to cover the wall and bottom surfaces of a first opening provided in a second insulating film 52 that has been formed on the first interlayer insulating film 51 with a liner insulating film 55 interposed therebetween. The capacitor insulating film 33 is formed along the first lower electrode 32 to cover it. The first upper electrode 34 is formed along the capacitor insulating film 33 to cover it. The first opening is formed to have a width H₁ which is larger than double the total sum of the film thickness d₁ of the first lower electrode 32 and the thickness d₂ of the capacitor insulating film 33.

A third interlayer insulating film 53, a liner insulating film 56, and a fourth interlayer insulating film 54 are successively formed on the second interlayer insulating film 52. Each of interconnects 73 formed in the fourth interlayer insulating film 54 is electrically connected to the corresponding first upper electrode 34 with a plug 72 interposed therebetween. Bit lines 74 are also formed in the fourth interlayer insulating film 54. Each of the bit lines 74 is electrically connected to the source/drain diffusion layer 24 which is different from that connected to the plug 71 with plugs 75 and 76 interposed therebetween.

Each of the fuse elements 41 is comprised of a second lower electrode 42 serving as the lower electrode of the fuse element, a fuse insulating film 43 formed on the upper surface of the second lower electrode 42, and a second upper electrode 44 formed on the fuse insulating film 43 and serving as the upper electrode of the fuse element. The second lower electrode 42 is buried in a second opening provided in the second interlayer insulating film 52 and has a columnar configuration. The second opening is formed to have a width H₂ which is smaller than double the film thickness d₁ of the first lower electrode 32.

The second lower electrodes 42 are electrically connected to diffusion regions 16 formed in the fuse region 12 of the substrate 10 with plugs 81 interposed therebetween.

The second upper electrodes 44 are electrically connected to interconnects 82 formed in the fourth interlayer insulating film 54 with plugs 83 interposed therebetween. Interconnects 84 are formed in the regions of the fourth interlayer insulating film 54 which are adjacent to the interconnects 82. The interconnects 84 are electrically connected to the diffusion layers 16 with plugs 85 and 86 interposed therebetween. Accordingly, when any of the fuse elements 41 undergoes dielectric breakdown and comes into a conductive state, the interconnects 82 and 84 are brought into a conductive state.

In the semiconductor device according to the present embodiment, the width H₂ of the second opening corresponding to the width of the second lower electrode 42 is adjusted to be less than double the film thickness d₁ of the first lower electrode 32. For example, when each of the first openings serving as capacitor holes in which the capacitors are to be formed has dimensions of 150 nm×380 nm, a conductive film with a thickness of about 20 nm is formed as the lower electrodes of the capacitors along the wall and bottom surfaces of the first opening. In this case, when each of the second openings serving as fuse holes is formed to have dimensions smaller than 40 nm square, the second opening is filled with the conductive film in forming the lower electrodes of the capacitors. This allows simultaneous formation of the second lower electrodes 42 of the fuse elements each having a columnar configuration and a width (diameter) of about 40 nm and the first lower electrodes 32 of the capacitors each having a depressed cross-sectional configuration and a thickness of about 20 nm. As a result, it is possible to simultaneously form concave capacitors and fuse elements which occupy a smaller area than the capacitors and thereby implement a semiconductor device wherein a region in which the fuse elements are formed occupies a smaller area. In the present embodiment, the cross-sectional configuration of each of the second lower electrodes 42 (second openings) may also be a circle. In that case, it is assumed that the width of each of the second lower electrodes 42 (second openings) indicates the diameter thereof.

As the width of the second opening serving as the fuse hole is smaller, the fuse element becomes smaller in size. However, when the width of the second opening is excessively small, it becomes difficult to fill the second opening with the conductive film and the capacitors and the fuse elements cannot be simultaneously performed any more. Accordingly, an optimal width is selected in consideration of the thickness of the conductive film to be formed and the height of each of the capacitors.

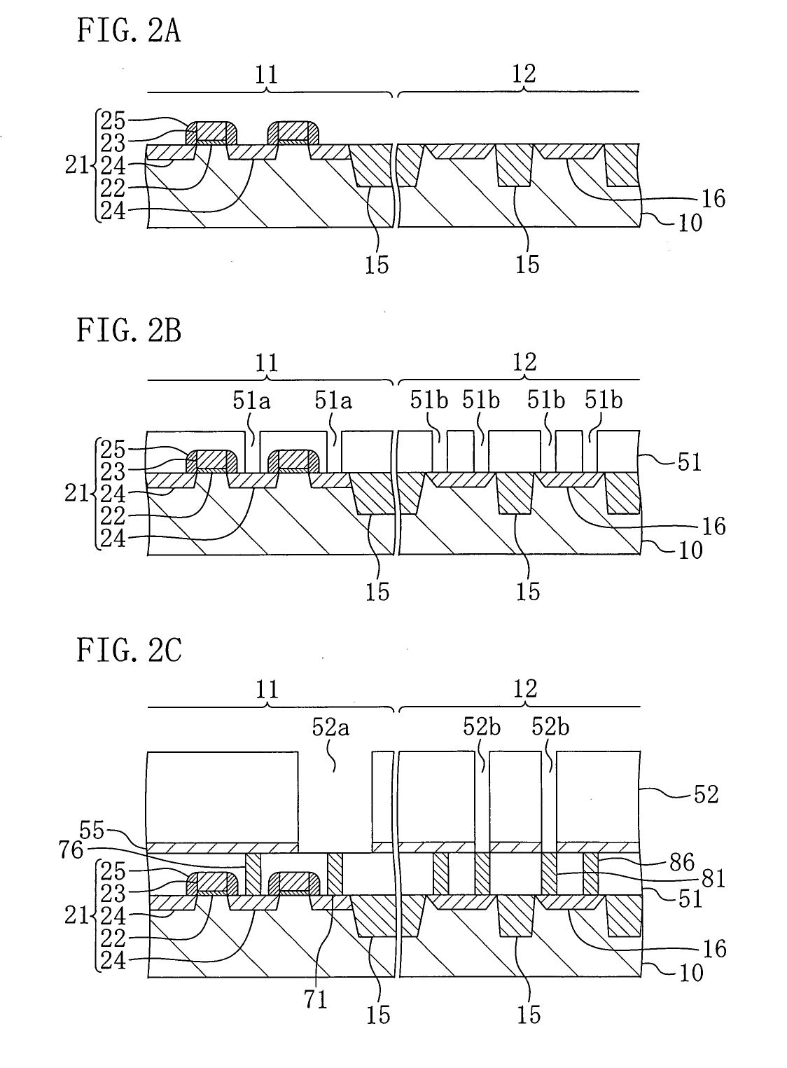

Next, a description will be given to a method for fabricating the semiconductor device according to the present embodiment with reference to the drawings. FIGS. 2A to 2C illustrate the method for fabricating the semiconductor device according to the present embodiment in the order in which the process steps thereof are performed.

First, as shown in FIG. 2A, the isolation film 15 is formed in the semiconductor substrate 10 by, e.g., a STI (Shallow Trench Isolation) method. Subsequently, after implantation for controlling the thresholds of transistors is performed, the transistors 21 are formed in the memory cell region 11 to be located on the plurality of element formation regions each defined by the isolation film 15.

The transistors 21 may be formed appropriately by a known method. Each of the gate electrodes 23 may be formed either of an amorphous silicon film or a polycrystalline silicon film or formed by using a polycide structure, a polymetal structure, a metal film, or the like. The sidewalls 25 formed on the side surfaces of the gate electrode 23 may be either single-layer sidewalls each made of a silicon nitride film or multilayer sidewalls each made of a silicon dioxide film and a silicon nitride film. It is also possible to form offset sidewalls between the gate electrode 23 and the sidewalls 25. It is also possible to form a structure which has lightly doped drain (LDD) regions, extension regions, or the like in addition to the source/drain diffusion layer 24. A nickel silicide layer or the like may also be formed on each of the source/drain regions 24.

The diffusion layers 16 are formed in the fuse region 12. The diffusion layers 16 may also be formed as the source/drain diffusion layers of a logic transistor (not shown) formed in the fuse region 12.

Next, as shown in FIG. 2B, an insulating film such as a silicon dioxide film is deposited by using a CVD (Chemical Vapor Deposition) method or the like. At this time, a liner insulating film composed of a silicon nitride film may also be deposited under the silicon dioxide film. Then, the surface thereof is polished by a CMP (Chemical Mechanical Polishing) method so that the first interlayer insulating film 51 composed of the silicon dioxide film having a planarized surface is formed. Subsequently, contact holes 51a reaching the source/drain regions 24 and contact holes 51b reaching the diffusion layers 16 are formed in the first interlayer insulating film 51 by using normal lithographic and etching technologies. In the case where a liner insulating film has been formed, the contact holes 51a and 51b become borderless contacts.

Next, as shown in FIG. 2C, a Ti film is deposited by using a sputtering method in each of the contact holes 51a and 51b formed in the first interlayer insulating film 51. After further depositing a TiN (titanium nitride) film and a W (tungsten) film in succession by using a CVD method, the respective portions the W film, the TiN film, and the Ti film which are located on the first interlayer insulating film 51 are removed by polishing using a CMP method so that the plugs 71, 76, 81, and 86 are individually formed.

Then, the liner insulating film 55 made of a silicon nitride film with a thickness of 30 nm to 50 nm is formed on the first interlayer insulating film 51 by using a CVD method or the like. Thereafter, the second interlayer insulating film 52 made of a silicon dioxide film with a thickness of 400 mn to 600 nm is formed. Subsequently, capacitor holes (first openings) 52a reaching the plugs 71 and fuse holes (second openings) 52b reaching the plugs 81 are formed in the second interlayer insulating film 52 and in the liner insulating film 55 by using normal lithographic and etching technologies. The configuration of each of the capacitor holes 52a and the fuse holes 52b is not limited to a rectangle. Each of the capacitor holes 52a and the fuse holes 52b may also be configured as a circle or the like.

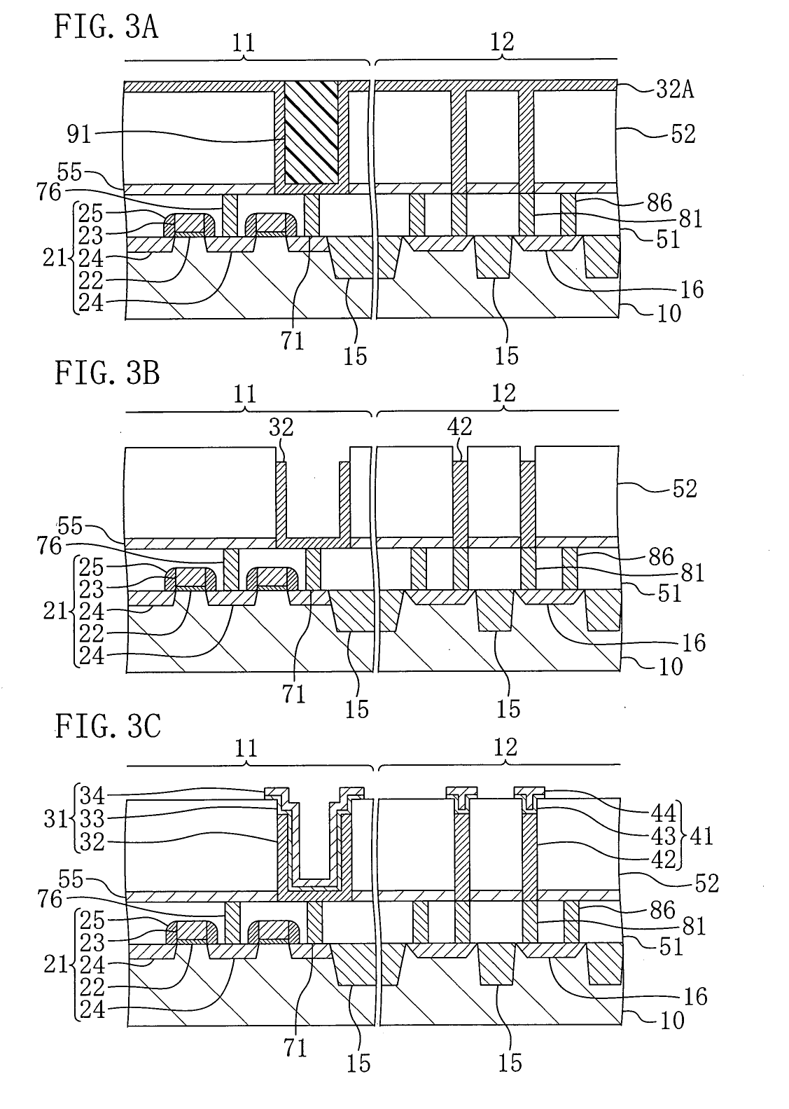

Next, as shown in FIG. 3A, a first conductive film 32A made of TiN (titanium nitride) and having a thickness of 10 nm to 50 nm is deposited on the second interlayer insulating film 52 by using a CVD method. When the film thickness of each of the first lower electrodes (first conductive film 32A) is d₁ and the width (diameter) of each of the fuse holes 52b is H₂, the fuse holes 52b are filled with TiN during the deposition such that 2d₁>H₂ is satisfied. On the other hand, the first conductive film 32A is formed along the wall and bottom surfaces of the capacitor holes 52a by adjusting the width H₁ of each of the capacitor holes 52a such that it is larger than double the total sum of the film thickness d₁ of each of the first lower electrodes 32 (first conductive film 32A) and the film thickness d₂ of each of the capacitor insulating films 33.

Subsequently, a resist film is formed on the first conductive film 32A and the portion thereof which is formed on the second interlayer insulating film 52 is etched back by a resist etch-back method so that a resist film 91 is selectively left only within the capacitor holes 52a.

It is also possible to remove the portion of the resist film which is formed on the second interlayer insulating film 52 by using an exposure apparatus. In this case, by using a specified mask pattern, it becomes possible to also form a planar capacitor for monitoring step-to-step variations in the capacitor and the like.

Next, as shown in FIG. 3B, the first conductive film 32A is subjected to an etch-back process using an anisotropic dry etching method, thereby forming the first lower electrodes 32 each having the depressed cross-sectional configuration in the capacitor holes 52a and forming the second lower electrodes 42 each having the columnar configuration in the fuse holes 52b.

Next, as shown in FIG. 3C, an insulating film composed of an oxide film of hafnium (Hf) and having a thickness of 5 nm to 15 nm is deposited on the second interlayer insulating film 52 by using an ALD-CVD (Atomic Layer Deposition) method or the like. Then, a second conductive film made of TiN and having a thickness of 20 nm to 50 nm is deposited. Thereafter, the insulating film and the second conductive film are patterned by using normal lithographic and etching technologies. As a result, the capacitors 31 each comprised of the capacitor insulating film 33 covering the first lower electrode 32 and of the first upper electrode 34 and the fuse elements 41 each comprised of the fuse insulating film 43 covering the second lower electrode 42 and of the second upper electrode 44 are formed. The second conductive film may also be a multilayer film of a TiN film formed by a CVD method and a TiN film formed by a sputtering method or the like.

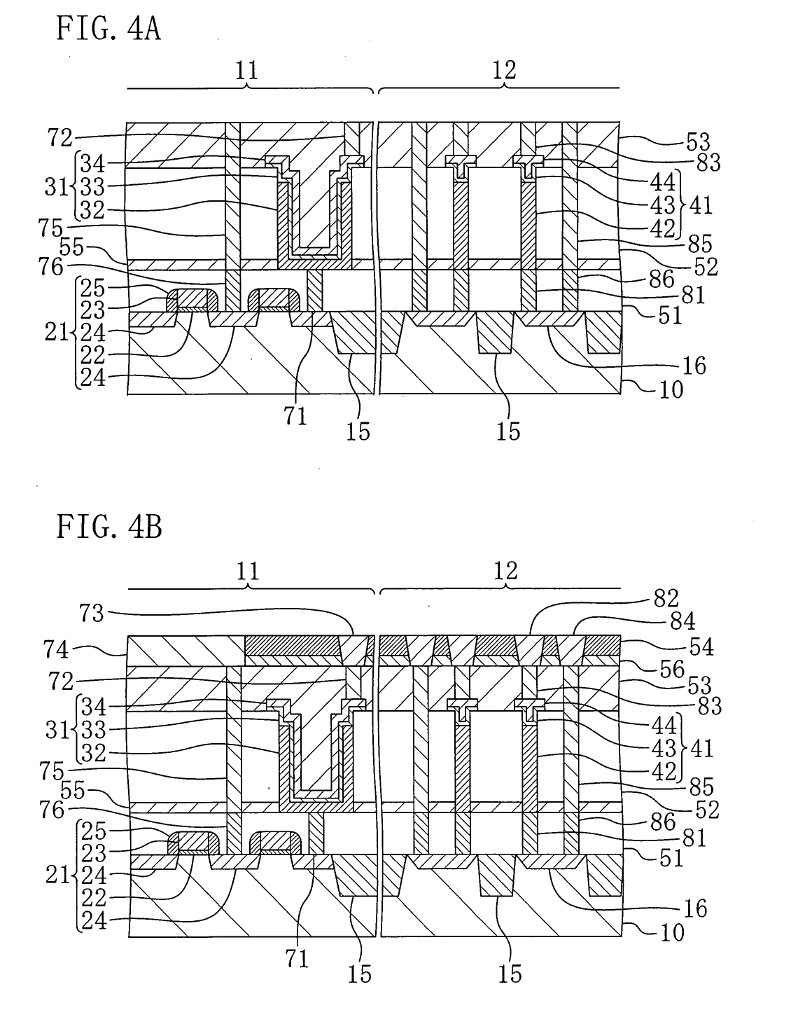

Next, as shown in FIG. 4A, the third interlayer insulating film 53 composed of a silicon dioxide film and having a thickness of 500 run to 800 nm is deposited on the second interlayer insulating film 52 by a CVD method or the like in such a manner as to cover the capacitors 31 and the fuse elements 41. Subsequently, the surface of the third interlayer insulating film 53 is polished and planarized by using a CMP method.

After the planarization of the surface, contact holes reaching the first upper electrodes 34, the second upper electrodes 44, and the plugs 76 and 86 are formed in the third interlayer insulating film 53 by using normal lithographic and etching technologies.

After an adhesion layer and tungsten are buried in each of the formed contact holes, polishing is performed by a CMP method so that the plugs 72 connected to the first upper electrodes 34 of the capacitors 31, the plugs 83 connected to the second upper electrodes 44 of the fuse elements, the plugs 75 connected to the plug 76, and the plugs 85 connected to the plugs 86 are formed.

Next, as shown in FIG. 4B, the liner insulating film 56 composed of a silicon nitride film and the fourth interlayer insulating film 54 composed of a silicon dioxide film are deposited and interconnect trenches are formed therein by using normal lithographic and etching technologies. After a seed barrier film is deposited in the formed interconnect trenches, a Cu film is formed by a plating method. Then, by polishing away the respective portions of the Cu film and the seed barrier film which are located on the fourth interlayer insulating film 54 by using a CMP method, the bit lines 74, the interconnects 73, and the interconnects 82 and 84 are individually formed.

In the semiconductor device according to the present embodiment, the width H₂ of each of the fuse holes 62b filled with the second lower electrodes 42 is adjusted to be less than double the film thickness d₁ of each of the first lower electrodes 32 of the capacitors 31. On the other hand, the width H₁ of each of the capacitor holes 52a filled with the first lower electrodes 32 is adjusted to be larger than double the total sum of the film thickness d₁ of each of the first lower electrodes 32 and the thickness d₂ of each of the capacitor insulating films 33. In other words, each of the capacitor holes 52a is formed to have the width H₁ which is larger than double the width H₂ of each of the fuse holes 52b. The arrangement allows the formation of the first lower electrodes 32 each having the depressed cross-sectional configuration in the capacitor holes 52a even when the thickness d₁ of the first conductive film 32A has been set such that each of the capacitor holes 52a is filled.

For example, when each of the capacitor holes 52a is formed to have dimensions of about 150 nm×380 nm, each of the fuse holes 52b may be formed appropriately to have dimensions of about 40 nm×40 nm. In this case, when the first conductive film 32A is formed to have the thickness d₁ of about 20 nm such that each of the fuse holes 52b is filled, the first conductive film 32A is formed along the wall and bottom surfaces of the capacitor holes 52a. As a result, it is possible to form the first lower electrodes 32 each having the depressed cross-sectional configuration and the second lower electrodes 42 each having the columnar structure by the same process.

In addition, by successively forming the insulating film and the conductive film on the second interlayer insulating film 52 and patterning them, the capacitor insulating films 33 and the first upper electrodes 34 as well as the fuse insulating films 43 and the second upper electrodes 44 are formed by the same process. This allows the capacitors 31 and the fuse elements 41 to be formed by the same process and thereby prevents an increase in the number of process steps.

When the capacitors 31 and the fuse elements 41 are formed by the same process steps using the same mask, the pitch at which the capacitors 31 are formed becomes undesirably the same as the pitch at which the fuse elements 41 are formed. However, in the present embodiment, the fuse elements 41 can be formed by far smaller in size than the capacitors 31. Accordingly, even when the fuse elements 41 are formed at the same pitch as the capacitors 31, the density at which the fuse elements 41 are formed can be increased and therefore the total area occupied by the fuse elements 41 can be reduced.

### Embodiment 2

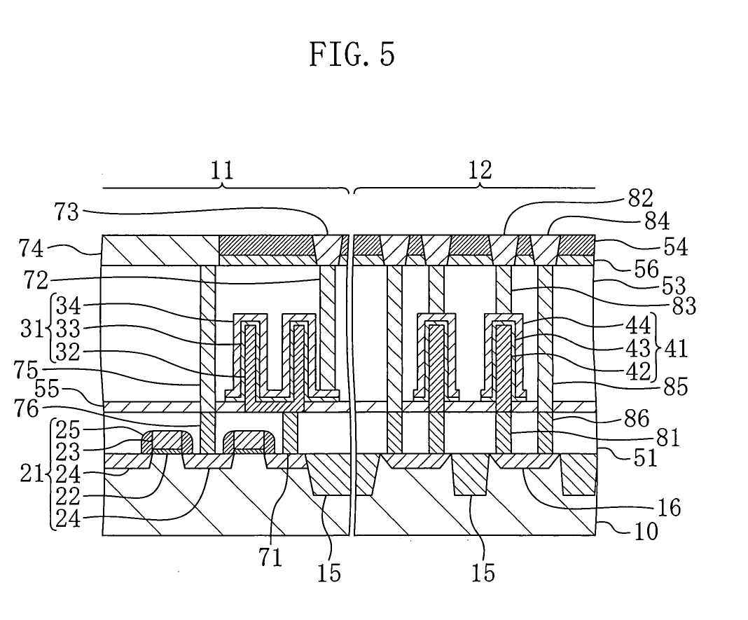

A second embodiment of the present invention will be described with reference to the drawings. FIG. 5 shows a cross-sectional structure of a semiconductor device according to the second embodiment. The description of the components shown in FIG. 5 which are the same as shown in FIG. 1 will be omitted by retaining the same reference numerals.

As shown in FIG. 5, the semiconductor device according to the present embodiment comprises cylindrical capacitors. In the semiconductor device according to the present embodiment, the heights of the fuse elements 41 are substantially equal to those of the capacitors 31 and the area occupied by each one of the fuse elements 41 is smaller. As a result, the effect of reducing a global level difference produced between the memory cell region 11 and the fuse region 12 can be achieved. This allows easy fine lithography when a wiring layer is formed on the third interlayer insulating film 53 and even allows an improvement in the reliability of interconnects.

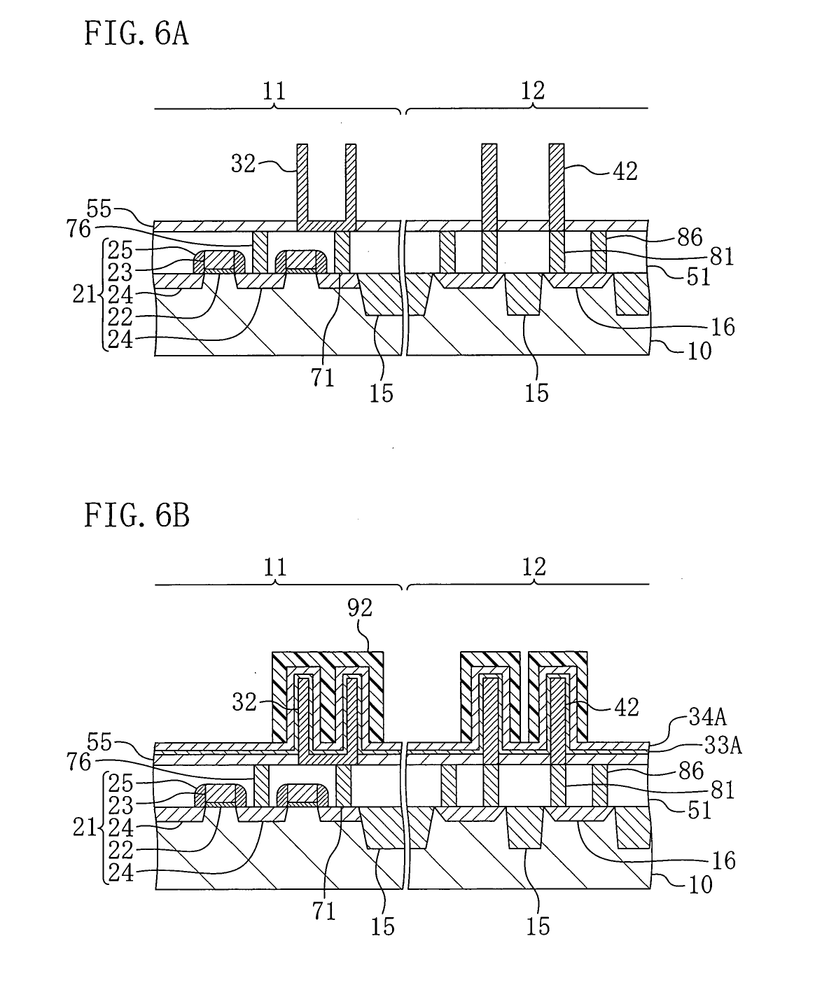

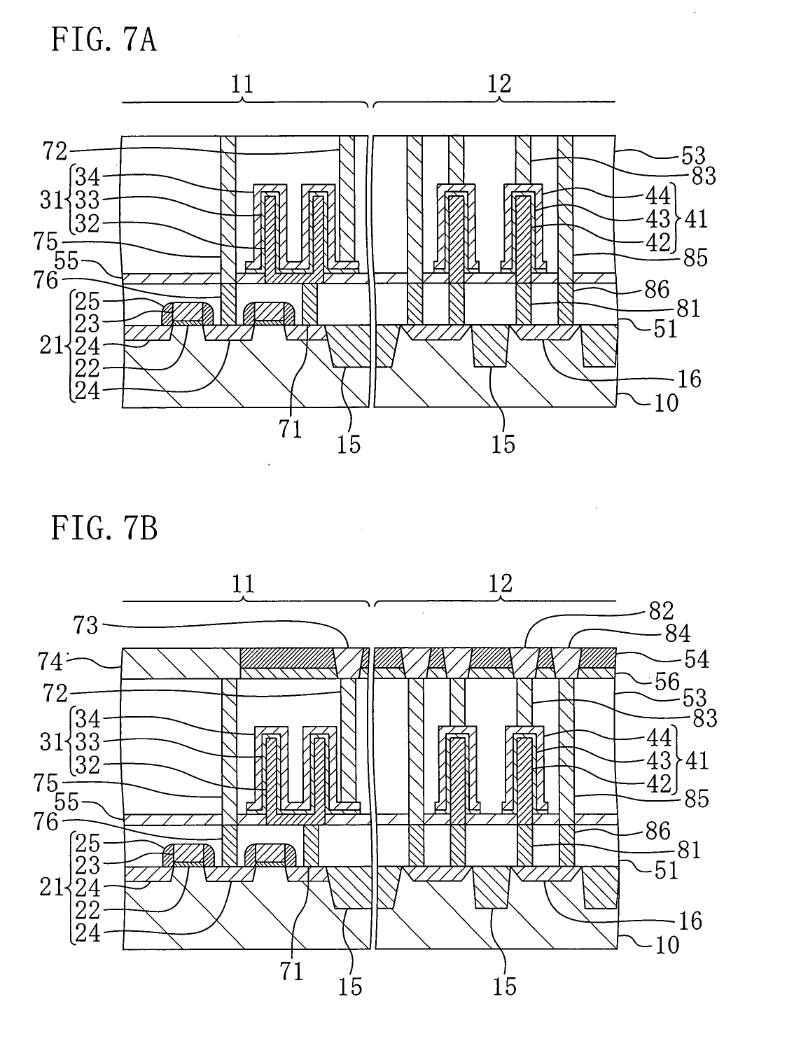

Next, a description will be given to a method for fabricating the semiconductor device according to the present embodiment with reference to the drawings. FIGS. 6A to 7B illustrate the method for fabricating the semiconductor device according to the second embodiment in the order in which the process steps thereof are performed. The process steps preceding and inclusive of the step of individually forming the first lower electrodes 32 and the second lower electrodes 42 in the capacitor holes 52a and the fuse holes 52b each formed in the second interlayer insulating film 52 are the same as in the first embodiment so that the description thereof will be omitted.

After the first lower electrodes 32 and the second lower electrodes 42 are formed as shown in FIG. 6A, the second interlayer insulating film 52 is etched away by using the liner insulating film 55 as a stopper. As a result, the first lower electrodes 32 each having a depressed cross-sectional configuration and the second lower electrodes 42 each having a columnar configuration are exposed.

Next, as shown in FIG. 6B, an insulating film 33A composed of an oxide film of Hf with a thickness of 5 nm to 15 nm is formed by an ALD-CVD method or the like in such a manner as to cover the first lower electrodes 32 and the second lower electrodes 42. Then, a second conductive film 34A made of TiN with a thickness of 20 nm to 50 nm is formed by a CVD method or the like. Subsequently, a resist film 92 covering the regions surrounding the first lower electrodes 32 and the second lower electrodes 42 are formed.

Next, as shown in FIG. 7A, the insulating film 33A and the second conductive film 34A are selectively etched by using the resist film 92 as a mask so that the capacitors 31 each comprised of the first lower electrode 32, the capacitor insulating film 33, and the first upper electrode 34 and the fuse elements 41 each comprised of the second lower electrode 42, the fuse insulating film 43, and the second upper electrode 44 are formed.

Subsequently, a silicon dioxide film with a thickness of 500 nm to 800 nm is deposited by a plasma CVD method or the like and the surface thereof is polished and planarized by a CMP method to form the third interlayer insulating film 53. Plug holes reaching the first upper electrodes 34, the second upper electrodes 44, and the plugs 76 and 86 are formed in the formed third interlayer insulating film by using normal lithographic and etching technologies. Subsequently, an adhesion layer and tungsten are buried in each of the plug holes and then polished by a CMP method so that the plugs 72 connected to the first upper electrodes 34, the plugs 83 connected to the second upper electrodes 44, the plugs 75 connected to the plugs 76, and the plugs 85 connected to the plugs 86 are formed.

Next, as shown in FIG. 7B, the liner insulating film 56 composed of a silicon nitride film and the fourth interlayer insulating film 54 composed of a silicon dioxide film are deposited and interconnect trenches are formed therein by using normal lithographic and etching technologies. A seed barrier film is deposited in the formed interconnect trenches and then a Cu film is formed by a plating method. Thereafter, the respective portions of the Cu film and the seed barrier film which are located on the fourth interlayer insulating film 54 are polished away by using a CMP method so that the bit lines 74 and the interconnects 73, 82, and 84 are formed.

Although each of the first and second embodiments has shown the example in which each of the second lower electrodes 42 has the same width (diameter) as each of the plugs 81, it is also possible to form the second lower electrodes 42 each having a width larger than that of each of the plugs 81 in consideration of an alignment margin and the like. In this case also, the number of the process steps does not increase and the area of the fuse region 12 hardly increases provided that the width of each of the second lower electrodes 42 is less than double the film thickness of each of the first lower electrodes 32.

In the example shown above, a metal oxide made of hafnium has been used for each of the capacitor insulating films and the fuse insulating films. The breakdown voltage of the oxide of hafnium (HfOx) is as low as 2.7 V to 2.9V so that it does not undergo dielectric breakdown at a voltage of not more than 1.5 V that is used for the operation of the capacitors. By applying 3.3 V that is a driving voltage for a logic transistor used in an I/O interface, dielectric breakdown can be easily caused. As a result, a low-voltage programmable semiconductor device can be obtained. However, the materials of the capacitor insulating films and the fuse insulating films are not necessarily limited to hafnium oxide. Instead of hafnium oxide, a composite oxide of hafnium oxide and aluminum oxide, zirconium oxide, or the like may also be used. It is also possible to use a film made of another dielectric material.

Thus, the semiconductor device according to the present invention and the fabrication method therefor can implement a semiconductor device wherein the area of a region on which fuse elements are formed can be reduced without increasing the number of process steps and are therefore useful as a semiconductor device having a memory circuit and a logic circuit each embedded therein and comprising fuse elements, a fabrication method therefor, and the like.

What is claimed is:

1. A semiconductor device comprising:
a capacitor including a first lower electrode, a capacitor insulating film, and a first upper electrode which are successively formed above a substrate; and
a fuse element including a second lower electrode, a fuse insulating film, and a second upper electrode which are successively formed above a different region of the substrate from a region thereof on which the capacitor is formed, wherein
the first lower electrode is formed to have a depressed cross-sectional configuration and
the second lower electrode has a columnar configuration and is made of the same conductive material as the first lower electrode.

2. The semiconductor device of claim 1, wherein a width of the second lower electrode is less than double a film thickness of the first lower electrode.

3. The semiconductor device of claim 1, wherein
the capacitor insulating film and the fuse insulating film are made of the same insulating material and
the first upper electrode and the second upper electrode are made of the same conductive material.

4. The semiconductor device of claim 1, further comprising:
a first interlayer insulating film formed on the substrate; and
a second interlayer insulating film formed on the first interlayer insulating film and having a first opening and a second opening each reaching the first interlayer insulating film, wherein
the first lower electrode is formed to cover the bottom and wall surfaces of the first opening,
the second lower electrode is formed to fill the second opening, and
a width of the first opening is larger than double a total sum of a film thickness of the first lower electrode and a thickness of the capacitor insulating film.

5. The semiconductor device of claim 4, wherein
the capacitor insulating film and the first upper electrode are formed to cover the side and upper surfaces of the first lower electrode and
the fuse insulating film and the second upper electrode are formed to cover the upper surface of the second lower electrode.

6. The semiconductor device of claim 1, further comprising:
a first interlayer insulating film formed on the substrate, wherein
the first lower electrode and the second lower electrode are formed to upwardly protrude from the upper surface of the first interlayer insulating film,
the capacitor insulating film and the first upper electrode are formed to cover the side and upper surfaces of the first lower electrode, and
the fuse insulating film and the second upper electrode are formed to cover the side and upper surfaces of the second lower electrode.

7. The semiconductor device of claim 1, wherein each of the capacitor insulating film and the fuse insulating film is made of a metal oxide.

8. The semiconductor device of claim 7, wherein the metal oxide is an oxide of hafnium.

9. A method for fabricating a semiconductor device, the method comprising the steps of:
(a) forming a first interlayer insulating film on a substrate;
(b) forming a second interlayer insulating film on the first interlayer insulating film and then forming a first opening and a second opening having a width smaller than a width of the first opening such that each of the first opening and the second opening extends through the formed second interlayer insulating film;
(c) after the step (b), forming a lower-electrode forming film above the substrate;
(d) removing a portion of the lower-electrode forming film which is formed on the upper surface of the second interlayer insulating film to form a first lower electrode having a depressed cross-sectional configuration in the first opening and form a second lower electrode having a columnar configuration in the second opening; and
(e) after the step (d), forming a capacitor insulating film covering the first lower electrode and a first upper electrode and simultaneously forming a fuse insulating film covering the second lower electrode and a second upper electrode.

10. The method of claim 9, wherein the second openings is formed in the step (b) to have a width which is less than double a thickness of the lower-electrode forming film.

11. The method of claim 9, wherein the first opening is formed in the step (b) to have a width which is larger than double a total sum of a thickness of the lower-electrode forming film and a thickness of the capacitor insulating film.

12. The method of claim 9, wherein the step (e) includes successively forming an insulating film and an upper-electrode forming film above the substrate and then patterning the insulating film and the upper-electrode forming film to form the capacitor insulating film and the first upper electrode as well as the fuse insulating film and the second upper electrode.

13. The method of claim 9, further comprising the step of:
after the step (d) and before the step (e), removing the second interlayer insulating film.
